(19) United States
(12) Patent Application Publication
(10) Pub. No.: US 2012/0257369 A1
(43) Pub. Date: Oct. 11, 2012

(54) EMI SHIELD AND ELECTRONIC DEVICE USING THE SAME

(75) Inventors: GUAN-DONG ZHAO, Shenzhen City (CN); XUE-FENG WAN, Shenzhen City (CN); ZHAO-YONG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen (CN)

(21) Appl. No.: 13/249,156

(22) Filed: Sep. 29, 2011

(30) Foreign Application Priority Data
Apr. 8, 2011 (CN) 201110088070.3

(51) Int. Cl. H05K 9/00

(52) U.S. Cl. 361/818; 174/351

(57) ABSTRACT

An EMI shield includes a first contacting member and a second contacting member connected to the first contacting member. The first contacting member includes a first bent portion and a second bent portion extending from the first bent portion. An opening is defined in the first bent portion. The second bent portion comprises a main body connected to and slanted to the first bent portion, a tongue-like sheet extending from the main body, towards and corresponding to the opening of the first bent portion, and one or more hooks formed on the sides of the main body. The tongue-like sheet includes a latching portion. An electronic device using the EMI shield is also provided.

### BACKGROUND

1. Technical Field

The present disclosure relates generally to an EMI shield, and particularly to an EMI shielding sheet and an electronic device using the same.

2. Description of Related Art

For shielding electromagnetic interference (EMI), an electronic device housing includes EMI shield. The EMI shield and the housing are fixed together via many screws. However, the assembly process of the electronic device is relatively complicated because the screws should be assembled one by one, and the assembly efficiency is relatively low.

Therefore, there is room for improvement within the art.

### BRIEF DESCRIPTION OF THE DRAWINGS

The components in the drawings are not necessarily drawn to scale, the emphasis instead placed upon clearly illustrating the principles of the present disclosure. Moreover, in the drawings, like reference numerals designate corresponding parts throughout the several views.

FIG. 1 is a partial, isometric view of an embodiment of an electronic device, including an EMI shield.

FIG. 2 is a partial, exploded, isometric view of the electronic device of FIG. 1.

FIG. 3 is an enlarged, isometric view of the EMI shield of the FIG. 1.

### DETAILED DESCRIPTION

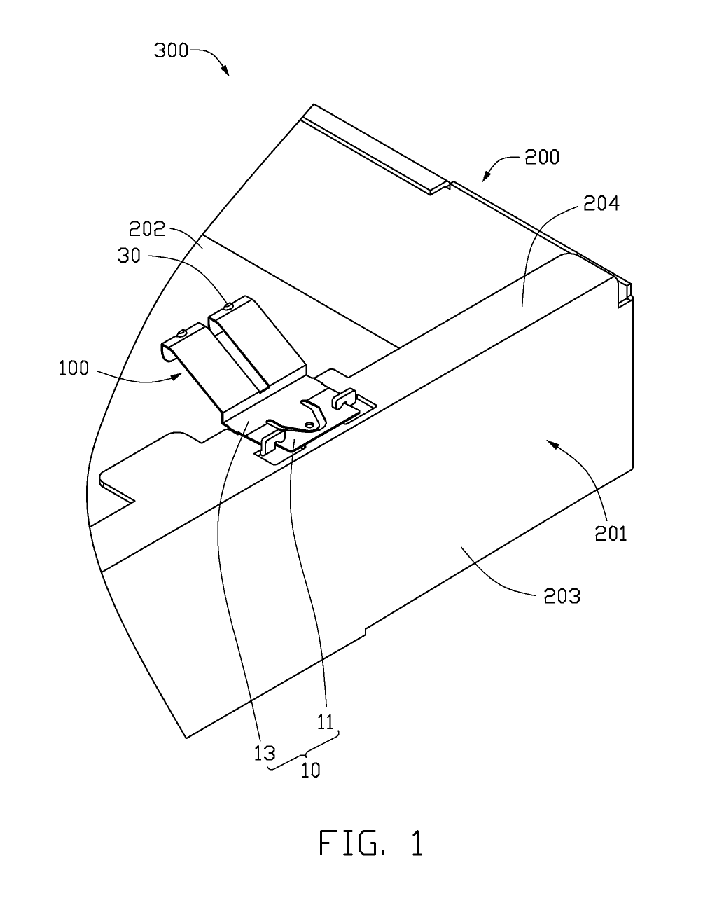

Referring to FIG. 1, an embodiment of an electronic device 300 includes a housing 200 and an EMI shield 100. The EMI shield 100 is in the form of a resilient sheet, and is used to shield electromagnetic interference emitted by various electronic components (not shown) in the housing 200. The EMI shield 100 is fixed to the housing 200. The electronic device 300 also includes other functional modules. However, for simplicity, only the housing 200 and the shield 100 are described.

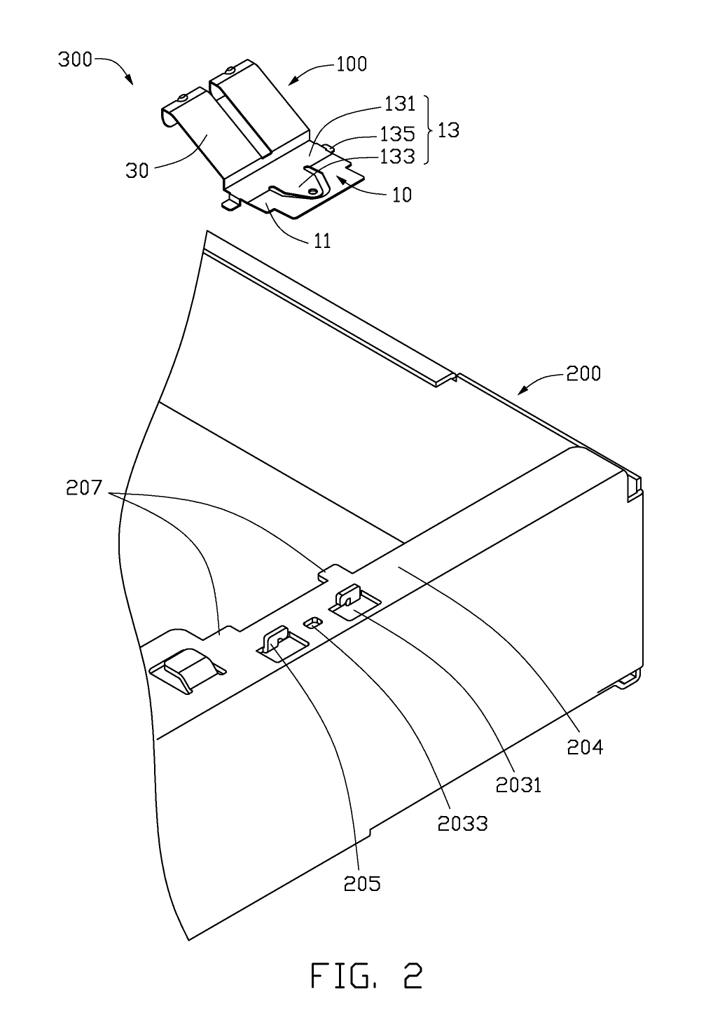

Referring also to FIG. 2, the housing 200 includes a sidewall 201, a base 202 and a cover (not shown). The sidewall 201 substantially perpendicularly extends from the periphery of the base 202, and the cover is placed on the sidewall 201, to cooperatively form a receiving space. The sidewall 201 includes a main body 203, a support portion 204, two hooks 205, and two engaging portions 207. The main body 203 is sheet-like and substantially perpendicularly extends from the periphery of the base 202. The support portion 204 extends from a top of the main body 203, towards an interior portion of the housing 200, and is substantially parallel to the base 202. Two punched holes 2031 and a latching hole 2033 are defined in the support portion 204 configured in alignment. Each punched hole 2031 is substantially rectangular. The latching hole 2033 is defined between the two punched holes 2031. The hooks 205 are substantially L-shaped, and extend upward from an edge of the corresponding punched hole 2031. The two hooks 205 are placed symmetrically relative to the hole 2033. Each of the engaging portions 207 has a substantially rectangular sheet-like shape, and is extended from the support portion 204 towards a center of the housing 200, and furthermore, is substantially coplanar with the support portion 204. The two engaging portions 207 are adjacent to the two hooks 205, respectively.

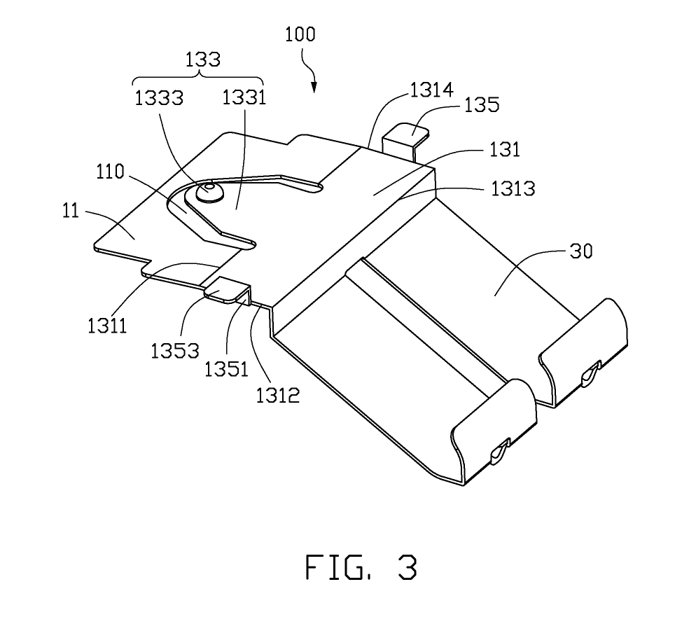

Referring also to FIG. 3, the EMI shield 100 includes a first contacting member 10 and a second contacting member 30 connected to the first contacting member 10. The first contacting member 10 is fixed to the sidewall 201, and the second contacting member 30 contacts the cover. Thus, the housing 200 thereby provides a function of shielding EMI.

The first contacting member 10 includes a first bent portion 11 and a second bent portion 13. The first bent portion 11 is substantially rectangular, and sheet-like. An opening 110 is defined in the first bent portion 11. The opening 110 is substantially U-shaped. The second bent portion 13 includes a main body 131, a tongue-like sheet 133, and a pair of hooks 135. The main body 131 is substantially rectangular, and sheet-like.

The main body 131 extends from a side of the first bent portion 11 adjacent to the opening 110. The main body 131 is slanted to the first bent portion 11 to define an angle in a range of about 4 degrees to about 5 degrees, and is elastically deformable relative to the first bent portion 11. The main body 131 includes a first side 1311, a second side 1312, a third side 1313, and a fourth side 1314, connected to each other in that order. The first side 1311 is connected to the first bent portion 11. The tongue-like sheet 133 extends from a center of the first side 1311, towards the opening 110. The tongue-like sheet 133 includes a base body 1331 and a latching portion 1333. The base body 1331 is substantially coplanar with the main body 131, and is deformable relative to the first bent portion 11. A shape of the base body 1331 substantially corresponds to the opening 110, and is elastically deformable corresponding to the opening 110. The latching portion 1333 is substantially a hemispheric protrusion, and is disposed on an end of the base body 1331 away from the first side 1311. The latching portion 1333 and the first bent portion 11 are disposed on opposite sides of the base body 1331. The two hooks 135 symmetrically extend from the second side 1312 and the fourth side 1314, respectively. Each hook 135 includes an extending portion 1351 and a bent portion 1353. The extending portion 1351 extends from a center portion of the second side 1312 along an extending direction of the latching portion 1333. Each bent portion 1353 extends perpendicularly from a free end of the extending portion 1351 away from the main body 131. The hooks 135 and the first bent portion 11 are disposed or located on opposite sides of the base body 1331. A quantity of the hooks 135 can be changed as needed, such as one, three, four, or more.

The second contacting member 30 is substantially sheet-like, and extends from the third side 1313.

Referring to FIGS. 1 through 3, the EMI shield 100 is fixed to the housing 200 as follows in the following steps. The first bent portion 11 is placed parallel to the support portion 204, and a free end of the first bent portion 11 is passed through the free ends of the two hooks 205, such that two sides of the first bent portion 11 are engaged with the two hooks 205, respectively, and the latching portion 1333 corresponds to the latching hole 2033. The two hooks 135 are engaged with the two engaging portions 207 by deforming the main body 131, respectively. The tongue-like sheet 133 is pressed to engage the latching portion 1333 in the latching hole 2033. The cover is placed on the sidewall 201 in contact with one end of the second contacting member 30. Thus, the EMI shield 100 is fixed to the housing 200, and the housing 200 can shield EMI.

Because the main body 131 is elastically deformable relative to the first bent portion 11, and the angle formed between the first bent portion 11 and the second bent portion 13 ranges from about 4 degrees to about 5 degrees, thus conveniently, the first bent portion 11 is engagable with the hooks 205, the latching portion 1333 is engagable with the latching hole 2033, and the hooks 135 are engagable with the engaging portion 207. Thus, in assembly, other elastic members may be omitted, and other assembling tools may also be omitted. The EMI shield 100 has a relatively simple structure, and a simple assembly process.

The latching portion 1333 may be a hole defined in the base body 1331, and correspondingly, a protrusion may thereby be placed on the main body 203.

It is believed that the present embodiments and their advantages will be understood from the foregoing description, and it will be apparent that various changes may be made thereto without departing from the spirit and scope of the disclosure or sacrificing all of its material advantages.

What is claimed is:

1. An EMI shield in the form of a resilient sheet, comprising:
a first contacting member comprising
a first bent portion defining an opening, and
a second bent portion extending from the first bent portion, and the second bent portion comprising a main body connected to and slanted to the first bent portion to define an angle, a tongue-like sheet extending from the main body towards the opening of the first bent portion, and one or more hooks formed on a side of the main body, respectively; and
a second contacting member connected to the main body of the second bent portion of the first contacting member, and opposite to the first bent portion.

2. The EMI shielding sheet of claim 1, wherein the angle is in a range of about 4 degrees to about 5 degrees.

3. The EMI shield of claim 1, wherein the tongue-like sheet comprises a base body extending from the main body towards the opening of the first bent portion, and a latching portion formed on the base body, and the base body of the tongue-like sheet is substantially coplanar with the main body of the first contacting member.

4. The EMI shield of claim 3, wherein the latching portion is a hole formed in the base body.

5. The EMI shield of claim 3, wherein the latching portion is a protrusion formed on a side of the base body away from the second contacting member.

6. The EMI shield of claim 1, wherein the hook is substantially L-shaped, and comprises an extending portion and a bent portion connected to the extending portion, the extending portion extends from the side of the main body, the bent portion extends perpendicularly from the extending portion away from the main body, and the hook and the first bent portion are disposed on opposite sides of the tongue-like sheet.

7. An EMI shield, comprising:
a first contacting member comprising
a first bent portion defining an opening, and
a second bent portion extending from the first bent portion, and the second bent portion comprising a main body connected to and slanted to the first bent portion to define an angle, a tongue-like sheet extending from the main body towards the opening of the first bent portion, and one or more hooks formed on a side of the main body, respectively; and
a second contacting member connected to the main body of the second bent portion of the first contacting member, and opposite to the first bent portion, wherein the main body and the tongue-like sheet are elastically deformable relative to the first bent portion.

8. The EMI shield of claim 7, wherein the angle is in a range of about 4 degrees to about 5 degrees.

9. The EMI shield of claim 7, wherein the tongue-like sheet comprises a base body extending from the main body towards the opening of the first bent portion, and a latching portion formed on the base body, and the base body of the tongue-like sheet is substantially coplanar with the main body of the first contacting member.

10. The EMI shield of claim 9, wherein the latching portion is a hole formed in the base body.

11. The EMI shield sheet of claim 9, wherein the latching portion is a protrusion formed on a side of the base body away from the second contacting member.

12. The EMI shield of claim 7, wherein the hook is substantially L-shaped, and comprises an extending portion and a bent portion connected to the extending portion, the extending portion extends from the side of the main body, the bent portion extends perpendicularly from the extending portion away from the main body, and the hook and the first bent portion are disposed on opposite sides of the tongue-like sheet.

13. An electronic device, comprising:
a housing comprising a sidewall, the sidewall comprising a support portion, one or more hooks formed on the support portion, one or more engaging portions formed on the support portion, and a latching hole defined in the support portion; and
an EMI shield, comprising:
a first contacting member comprising
a first bent portion defining an opening, and
a second bent portion extending from the first bent portion, and the second bent portion comprising a main body connected to and slanted to the first bent portion to define an angle, a tongue-like sheet extending from the main body towards the opening of the first bent portion, and one or more hooks formed on a side of the main body; and
a second contacting member connected to the main body of the second bent portion of the first contacting member and opposite to the first bent portion,
wherein the main body and the tongue-like sheet are elastically deformable relative to the first bent portion, the tongue-like sheet comprises a latching portion, the hooks of the sidewall engage with the sides of the first bent portion, the engaging portion of the sidewall engages with the hooks of the second bent portion, and the latching portion of the tongue-like sheet is engaged in the latching hole of the sidewall.

14. The electronic device of claim 13, wherein the angle is in a range of about 4 degrees to about 5 degrees.

15. The electronic device of claim 13, wherein the tongue-like sheet comprises a base body extending from the main body towards the opening of the first bent portion, and a latching portion formed on the base body, and the base body of the tongue-like sheet is substantially coplanar with the main body of the first contacting member.

16. The electronic device of claim 15, wherein the latching portion is a hole formed in the base body.

17. The electronic device of claim 15, wherein the latching portion comprise a protrusion formed on a side of the base body away from the second contacting member.

18. The electronic device of claim 13, wherein the hook is substantially L-shaped, and comprises an extending portion and a bent portion connected to the extending portion, the extending portion extends from the side of the main body, the bent portion extends perpendicularly from the extending portion away from the main body, and the hook and the first bent portion are disposed on opposite sides of the tongue-like sheet.
